(19) United States
(12) Patent Application Publication
(10) Pub. No.: US 2025/0140759 A1
(43) Pub. Date: May 1, 2025

(54) METHOD OF MANUFACTURING FILM ASSEMBLY FOR TRANSFERRING LIGHT EMITTING ELEMENT, FILM ASSEMBLY, AND METHOD OF MANUFACTURING DISPLAY DEVICE USING FILM ASSEMBLY

(71) Applicant: Samsung Display Co., LTD., Yongin-si (KR)

(72) Inventors: Jeong Won HAN, Yongin-si (KR); Han Chun RYU, Yongin-si (KR)

(21) Appl. No.: 18/771,623

(22) Filed: Jul. 12, 2024

(30) Foreign Application Priority Data
Nov. 1, 2023 (KR) 10-2023-0149329

(51) Int. Cl. H01L 25/075

(52) U.S. Cl. CPC H01L 25/0753

(57) ABSTRACT

A method of manufacturing a film assembly for transferring a light emitting element is provided. The film assembly includes: a base portion; a stamp layer on the base portion; and a protective film on the stamp layer. The method includes: forming a first cutting area in the film assembly comprising exposing at least a portion of the stamp layer; and forming a second cutting area in the film assembly comprising entirely penetrating the film assembly. The forming of the second cutting area is performed after the forming of the first cutting area.

### CROSS-REFERENCE TO RELATED APPLICATION

The present application claims priority to and the benefit of Korean Patent Application No. 10-2023-0149329, filed on Nov. 1, 2023, in the Korean Intellectual Property Office, the entire disclosure of which is incorporated herein by reference.

### BACKGROUND

### 1. Field

Aspects of embodiments of the present disclosure relate to a method of manufacturing a film assembly for transferring a light emitting element, a film assembly, and a method of manufacturing a display device using the film assembly.

### 2. Description of the Related Art

Recently, as interest in an information display is increasing, research and development into display devices is being continuously conducted. The display device may include a light emitting element as a light source. The light emitting element may be transferred onto a substrate for manufacturing a display device by using various methods.

For example, a light emitting element may be transferred onto the backplane of a display device by using a stamp film including one or more layers. The stamp film may include fine structures to appropriately transfer a light emitting element having a relatively small size.

When a manufacturing error occurs in the structure formed on the stamp film, there may be a risk of manufacturing defects occurring during the transfer process of the light emitting element. Accordingly, a method for carefully manufacturing the stamp film and the like and that reduces process risks during the transfer process of a light emitting element is desired.

### SUMMARY

Embodiments of the present disclosure provide a method of manufacturing a film assembly for transferring a light emitting element, a film assembly, and a method of manufacturing a display device using the film assembly in which the quality of a film assembly for transferring a light emitting element is improved, the risk of manufacturing defects is reduced, and the transfer reliability and precision of a light emitting element is improved.

An embodiment of the present disclosure provides a method of manufacturing a film assembly for transferring a light emitting element. The film assembly includes: a base portion; a stamp layer on the base portion; and a protective film on the stamp layer. The method includes: forming a first cutting area in the film assembly comprising exposing at least a portion of the stamp layer; and forming a second cutting area in the film assembly comprising entirely penetrating the film assembly. The forming of the second cutting area is performed after the forming of the first cutting area.

The forming of the first cutting area may include entirely penetrating the protective film but not entirely penetrating the base portion and the stamp layer.

The forming of the second cutting area may include forming a plurality of unit areas that are separated from each other.

The plurality of unit areas may be determined based on a shape of the second cutting area.

The forming of the second cutting area may include cutting at least a portion of the film assembly by using a pinnacle mold.

The film assembly may have a pin-hole for aligning a position of the pinnacle mold, and the pin-hole may penetrate at least the protective film.

At least a portion of the protective film may not be on the base portion and the stamp layer, and the pin-hole may be in the at least a portion of the protective film.

The pin-hole may include a first pin-hole formed in a first side of the film assembly and a second pin-hole formed in a second side of the film assembly.

In the forming of the second cutting area, the film assembly may be on a film manufacturing base, and a polymer lower film may be between the film manufacturing base and the base portion.

According to an embodiment of the present disclosure, a film assembly for transferring a light emitting element is provided. The film assembly includes: a base portion; a stamp layer on the base portion; and a protective film on the stamp layer. A first cutting area is formed in the protective film but is not formed in the stamp layer and the base portion, and a second cutting area entirely penetrates the base portion, the stamp layer, and the protective film.

According to an embodiment of the present disclosure, a method of manufacturing a display device includes: preparing a film assembly, the film assembly including a base portion, a stamp layer on the base portion, and a protective film on the stamp layer; coupling the film assembly and a stamp head; bending at least a portion of the film assembly; removing at least a portion of the protective film; and transferring a light emitting element onto a pixel circuit layer by using the film assembly coupled to the stamp head. The film assembly has a first cutting area and a second cutting area. The first cutting area is formed in the protective film but is not formed in the stamp layer and the base portion, and the second cutting area entirely penetrates the base portion, the stamp layer, and the protective film.

The film assembly may include a plurality of unit areas defined by the second cutting area, and the coupling of the film assembly and the stamp head may include coupling a portion of the film assembly in at least one of the plurality of unit areas to the stamp head.

The bending of at least a portion of the film assembly may include bending an edge portion of the film assembly based on the first cutting area.

The removing at least a portion of the protective film may include: removing at least a portion of the protective film surrounded by the first cutting area; and exposing at least a portion of the stamp layer.

The light emitting element may include a flip chip type micro light emitting diode.

According to embodiments of the present disclosure, a method of manufacturing a film assembly for transferring a light emitting element, a film assembly, and a method of manufacturing a display device by using the film assembly in which the quality of a film assembly for transferring a light emitting element may be improved, the risk of manufacturing defects may be reduced, and the transfer reliability and precision of a light emitting element may be improved.

### BRIEF DESCRIPTION OF THE DRAWINGS

FIG. 1 illustrates a top plan view of a display device according to an embodiment.

FIG. 2 illustrates a pixel in the display device shown in FIG. 1 according to an embodiment.

FIG. 3 illustrates a cross-sectional view of a display device according to an embodiment.

FIG. 4 is a flowchart describing a method of manufacturing a film assembly according to an embodiment.

FIG. 5 illustrates a schematic top plan view of a film assembly according to an embodiment.

FIG. 6 to FIG. 8 illustrate schematic top plan views of steps of a method of manufacturing a film assembly according to an embodiment.

FIG. 9 to FIG. 12 illustrate schematic cross-sectional views of steps of a method of manufacturing a film assembly according to an embodiment.

FIG. 13 is a flowchart describing a method of manufacturing a display device according to an embodiment.

FIG. 14 to FIG. 25 illustrate cross-sectional views of steps of a method of manufacturing a display device according to an embodiment.

### DETAILED DESCRIPTION

The present disclosure may be variously modified and may have various forms. Accordingly, embodiments will be illustrated and described in detail in the following. This, however, does not limit the present disclosure to the described embodiments, and the present disclosure is to be understood as embracing all embodiments included in the spirit and scope of the present disclosure, including all changes, equivalents, and substitutes.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Embodiments of the present disclosure relate to a manufacturing method of a film assembly for transferring a light emitting element, a film assembly, and a manufacturing method of a display device using the film assembly. Hereinafter, a method of manufacturing a film assembly for transferring a light emitting element, a film assembly, and a method of manufacturing a display device using the film assembly according to an embodiment will be described with reference to the accompanying drawings.

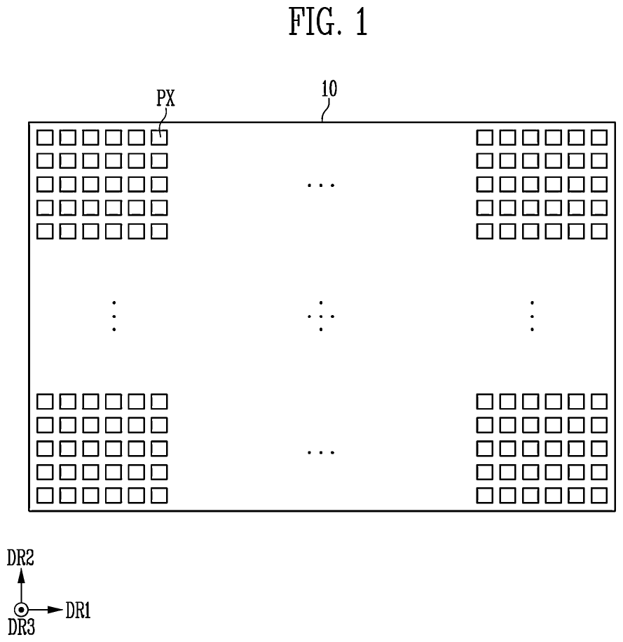

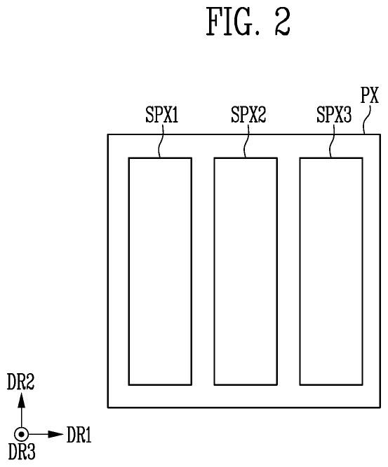

FIG. 1 illustrates a top plan view of a display device according to an embodiment. FIG. 2 illustrates a pixel in the display device shown in FIG. 1 according to an embodiment.

Referring to FIG. 1, a display device 10 is configured to output information in the form of light (e.g., to output light information). For example, the display device 10 is a device for displaying a moving image and/or a still image and may be used as a display screen of a portable electronic device, such as a mobile phone, a smart phone, a tablet personal computer (PC), a smart watch, a watch phone, a mobile communication terminal, an electronic note, an electronic book, a portable multimedia players (PMP), a navigation device, and an ultra-mobile PC (UMPC), and may be used as display screens of various products, such as a television set, a laptop computer, a monitor, a billboard, an Internet of Things (IOT) device, etc.

The display device 10 may be formed as a flat surface having a rectangular shape having a long side of a first direction DR1 and a short side of a second direction DR2 crossing the first direction DR1. A corner at where the long side in the first direction DR1 and the short side in the second direction DR2 meet may be rounded to have a curvature (e.g., a predetermined curvature) or may be formed to have a right angle. The flat shape of the display device 10 is not limited to a quadrangular shape, and the display device 10 may be formed to have another polygonal, circular, or elliptical shape. The display device 10 may be formed to be flat but is not limited thereto. For example, the display device 10 may have curved portions at left and right ends (or sides) and which may have a constant curvature or a variable curvature. In addition, the display device 10 may be flexibly formed (e.g., may be formed of a flexible material) to be bent, curved, folded, or rolled.

The display device 10 may further include pixels PX, scan wires extending in the first direction DR1, and data wires extending in the second direction DR2 to display an image. The pixels PX may be arranged in a matrix format (or matrix pattern) in the first direction DR1 and the second direction DR2.

Each of the pixels PX may include a plurality of sub-pixels SPX1, SPX2, and SPX3 as shown in FIG. 2. FIG. 2 illustrates an embodiment in which each of the pixels PX includes three sub-pixels SPX1, SPX2, and SPX3, that is, a first sub-pixel SPX1, a second sub-pixel SPX2, and a third sub-pixel SPX3, but the present disclosure is not limited thereto.

The first sub-pixel SPX1, the second sub-pixel SPX2, and the third sub-pixel SPX3 may be connected to one of the data wires and at least one of the scan wires.

Each of the first sub-pixel SPX1, the second sub-pixel SPX2, and the third sub-pixel SPX3 may have a rectangular, square, or rhombus planar shape. For example, each of the first sub-pixel SPX1, the second sub-pixel SPX2, and the third sub-pixel SPX3 may have a rectangular planar shape having short sides in the first direction DR1 and long sides in the second direction DR2 as shown in, for example, FIG. 2. In other embodiments, each of the first sub-pixel SPX1, the second sub-pixel SPX2, and the third sub-pixel SPX3 may have a square or rhombus planar shape having sides of the same length in the first direction DR1 and the second direction DR2.

As shown in FIG. 2, the first sub-pixel SPX1, the second sub-pixel SPX2, and the third sub-pixel SPX3 may be arranged in (e.g., may be adjacent to each other in) the first direction DR1. In other embodiments, one of the second sub-pixel SPX2 and the third sub-pixel SPX3 and the first sub-pixel SPX1 may also be arranged in the first direction DR1, and the other thereof and the first sub-pixel SPX1 may be arranged in the second direction DR2.

In other embodiments, one of the first sub-pixel SPX1 and the third sub-pixel SPX3 and the second sub-pixel SPX2 may be arranged in the first direction DR1, and the other one thereof and the second sub-pixel SPX2 may be arranged in the second direction DR2. In other embodiments, one of the first sub-pixel SPX1 and the second sub-pixel SPX2 and the third sub-pixel SPX3 may be arranged in the first direction DR1, and the other one thereof and the third sub-pixel SPX3 may be arranged in the second direction DR2.

The first sub-pixel SPX1 may emit first light, the second sub-pixel SPX2 may emit second light, and the third sub-pixel SPX3 may emit third light. In one embodiment, the first light may be light of a red wavelength band, the second light may be light of a green wavelength band, and the third light may be light of a blue wavelength band. The red wavelength band is a wavelength band in a range of about 600 nm to about 750 nm, the green wavelength band is a wavelength band in a range of about 480 nm to about 560 nm, and the blue wavelength band is a wavelength band in a range of about 370 nm to about 460 nm, but they are not limited thereto.

Each of the first sub-pixel SPX1, the second sub-pixel SPX2, and the third sub-pixel SPX3 is a light emitting element emitting light and may include an inorganic light emitting element including an inorganic semiconductor. For example, the inorganic light emitting element may be a flip chip-type micro light emitting diode (LED), but the embodiments of the present disclosure are not limited thereto.

As shown in the embodiment illustrated in FIG. 2, an area of the first sub-pixel SPX1, an area of the second sub-pixel SPX2, and an area of the third sub-pixel SPX3 may be substantially the same, but the embodiments of the present disclosure are not limited thereto. At least one of the area of the first sub-pixel SPX1, the area of the second sub-pixel SPX2, and the area of the third sub-pixel SPX3 may be different from another one(s) thereof. In another embodiment, two of the area of the first sub-pixel SPX1, the area of the second sub-pixel SPX2, and the area of the third sub-pixel SPX3 may be substantially the same, and the other one thereof may be different from the two. In another embodiment, the area of the first sub-pixel SPX1, the area of the second sub-pixel SPX2, and the area of the third sub-pixel SPX3 may be different from each other.

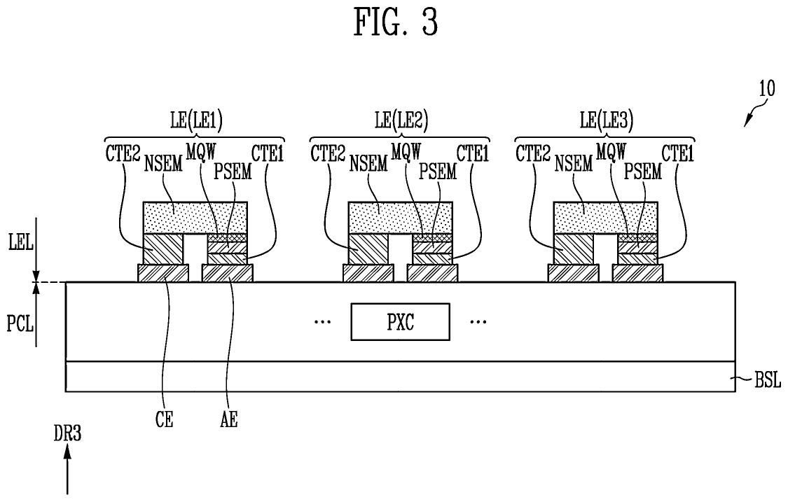

FIG. 3 illustrates a cross-sectional view of a display device according to an embodiment. Referring to FIG. 3, the display device 10 may include a pixel circuit layer PCL and a light emitting element layer LEL.

The pixel circuit layer PCL may be a layer including a pixel circuit PXC for driving light emitting elements LE. The pixel circuit layer PCL may be a backplane layer. The pixel circuit layer PCL may include a base layer BSL, metal layers for forming the pixel circuits PXC, and insulating layers disposed between the metal layers. In some embodiments, the base layer BSL may be a base substrate or a base member for supporting the display device 10. In one embodiment, the base layer BSL may be a rigid substrate made of a glass material. In one embodiment, the base layer BSL may include a silicon material. In one embodiment, the base layer BSL may be a flexible substrate that is bendable, foldable, or rollable. In such an embodiment, the base layer BSL may include an insulating material, such as a polymer resin, such as a polyimide. In some embodiments, the pixel circuits PXC may include transistors. For example, the pixel circuits PXC may include thin film transistors. The pixel circuits PXC may further include storage capacitors. The pixel circuits PXC may be electrically connected to the light emitting elements LE to provide electrical signals for (e.g., to cause) the light emitting elements LE to emit light.

The light emitting element layer LEL may be disposed on the pixel circuit layer PCL. The light emitting element layer LEL includes pixel electrodes AE, common electrodes CE, and the light emitting elements LE. Each of the first sub-pixel SPX1, the second sub-pixel SPX2, and the third sub-pixel SPX3 includes the light emitting element LE connected to the pixel electrode AE and the common electrode CE. In some embodiments, the light emitting elements LE may include a first light emitting element LE1 configured to emit light of a first color and included in the first sub-pixel SPX1, a second light emitting element LE2 configured to emit light of a second color and included in the second sub-pixel SPX2, and a third light emitting element LE3 configured to emit light of a third color and included in the third sub-pixel SPX3. The pixel electrode AE may be referred to as an anode electrode, and the common electrode CE may be referred to as a cathode electrode.

The pixel electrodes AE and the common electrodes CE may be disposed on the pixel circuit layer PCL. Each of the pixel electrodes AE may be electrically connected to the pixel circuit PXC of the pixel circuit layer PCL. Accordingly, a pixel voltage (or an anode voltage) controlled by the pixel circuit PXC (e.g., a transistor) may be applied to the pixel electrode AE.

Each of the common electrodes CE may be electrically connected to a power wire formed in the pixel circuit layer PCL. Accordingly, a power supply voltage (e.g., a single power supply voltage) of the power wire may be applied to the common electrodes CE.

The pixel electrodes AE and the common electrodes CE may include a highly reflective metallic material, such as a stacked structure of aluminum and titanium (Ti/Al/Ti), a stacked structure of aluminum and an ITO (ITO/AI/ITO), an APC alloy, and a stacked structure of an APC alloy and an ITO (ITO/APC/ITO). The APC alloy is an alloy of silver (Ag), palladium (Pd), and copper (Cu). However, the present disclosure is not limited thereto.

FIG. 3 illustrates an embodiment in which each of the light emitting elements LE is a flip-chip type micro LED in which a first contact electrode CTE1 and a second contact electrode CTE2 are disposed to face the pixel electrode AE and the common electrode CE. However, the shape of the light emitting element LE is not limited thereto.

The light emitting element LE may include an inorganic material (e.g., GaN). A length in the first direction DR1, a length in the second direction DR2, and a length in the third direction DR3 of the light emitting element LE may be in a range of several μm to several hundred μm, respectively. For example, the length in the first direction DR1, the length in the second direction DR2, and the length in the third direction DR3 of the light emitting element LE may be about 100 μm or less, respectively. However, the present disclosure is not limited thereto.

Each light emitting element LE may be a light emitting structure including an n-type semiconductor NSEM, an active layer MQW, a p-type semiconductor PSEM, a first contact electrode CTE1, and a second contact electrode CTE2.

A portion of the n-type semiconductor NSEM may be disposed on the active layer MQW. A portion of the n-type semiconductor NSEM may be disposed on the second contact electrode CTE2. In some embodiments, one surface of the n-type semiconductor NSEM may face the display surface. The n-type semiconductor NSEM may be made of GaN doped with an n-type conductive dopant, such as Si, Ge, or Sn.

The active layer MQW may be disposed on a portion of one surface of the n-type semiconductor NSEM. The active layer MQW may be interposed between the n-type semiconductor NSEM and the p-type semiconductor PSEM. The active layer MQW may include a material having a single or multiple quantum well structure. When the active layer MQW includes a material having a multi-quantum well structure, a plurality of well layers and a barrier layer may be alternately stacked on each other. In such an embodiment, the well layer may be formed of InGaN, and the barrier layer may be formed of GaN or AlGaN but are not limited thereto. In another embodiment, the active layer MQW may have a structure in which a semiconductor material having large band gap energy and a semiconductor material having small band gap energy are alternately stacked on each other or may include group 3 to group 5 semiconductor materials according to a wavelength band of light to be emitted.

The p-type semiconductor PSEM may be disposed on one surface of the active layer MQW. The p-type semiconductor PSEM may be made of GaN doped with a p-type conductive dopant, such as Mg, Zn, Ca, Se, or Ba.

The first contact electrode CTE1 may be disposed on the p-type semiconductor PSEM, and the second contact electrode CTE2 may be disposed on the other portion of one surface of the n-type semiconductor NSEM. The other portion of one surface of the n-type semiconductor NSEM on which the second contact electrode CTE2 is disposed may be spaced apart from one portion of one surface of the n-type semiconductor NSEM on which the active layer MQW is disposed.

The first contact electrode CTE1 and the pixel electrode AE may be bonded to each other through a conductive adhesive member, such as an anisotropic conductive film (ACF) or an anisotropic conductive paste (ACP). The first contact electrode CTE1 and the pixel electrode AE may be bonded to each other through a laser bonding process. The first contact electrode CTE1 and the pixel electrode AE may be bonded to each other through a soldering process.

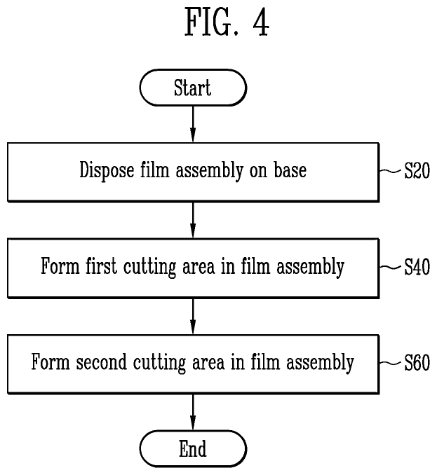

Next, a method of manufacturing a film assembly FAS for transferring the light emitting element LE will be described with reference to FIG. 4 to FIG. 12. Descriptions that may be redundant to those provided above may be simplified or may not be repeated.

FIG. 4 is a schematic flowchart describing steps of a method of manufacturing a film assembly according to an embodiment.

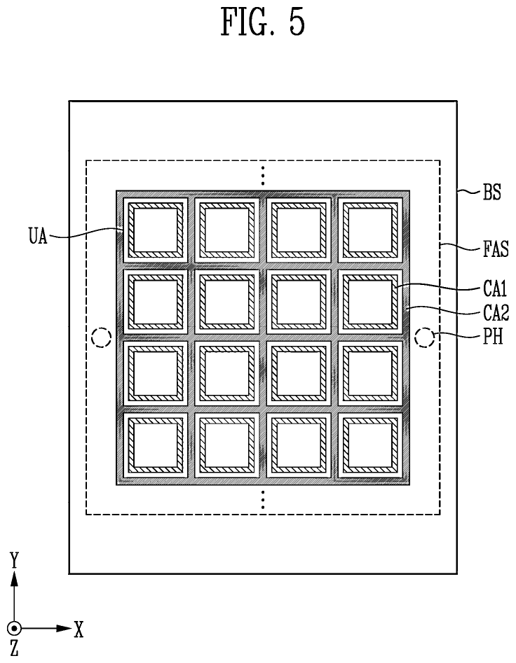

FIG. 5 illustrates a schematic top plan view of a film assembly according to an embodiment. FIG. 5 illustrates the film assembly FAS that is prepared to transfer the light emitting element LE and in which the manufacturing process of the film assembly FAS is nearly or substantially completed.

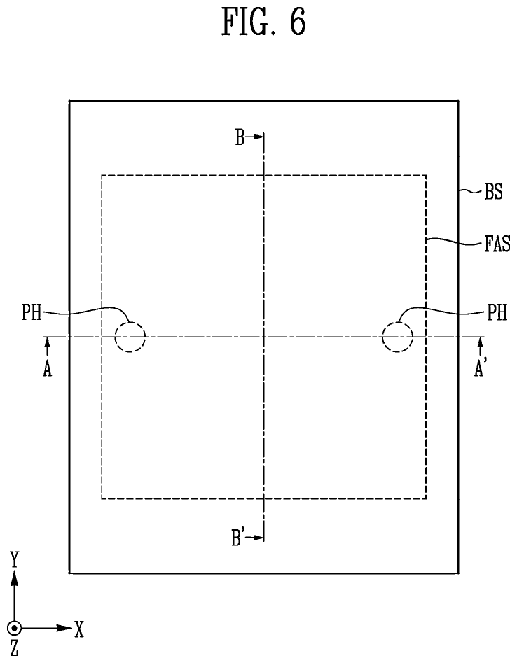

FIG. 6 to FIG. 8 illustrate schematic top plan views of steps of a method of manufacturing a film assembly according to an embodiment. For better understanding and ease of description, FIG. 6 to FIG. 8 illustrate the film assembly FAS based on the planar structure of the film assembly FAS illustrated with reference to FIG. 5 and illustrate the planar structure in which the film assembly FAS includes a single unit area so that the illustration of the drawing is clearer.

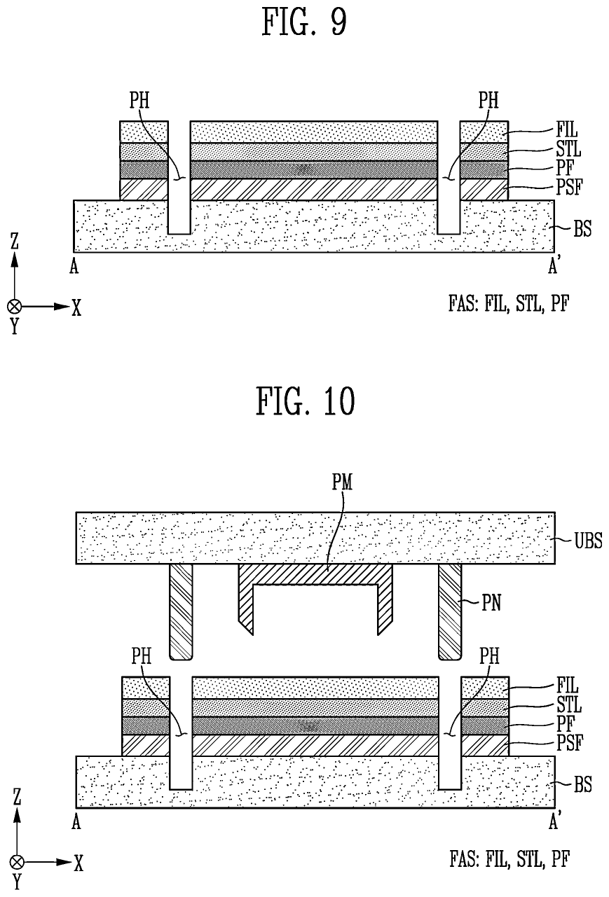

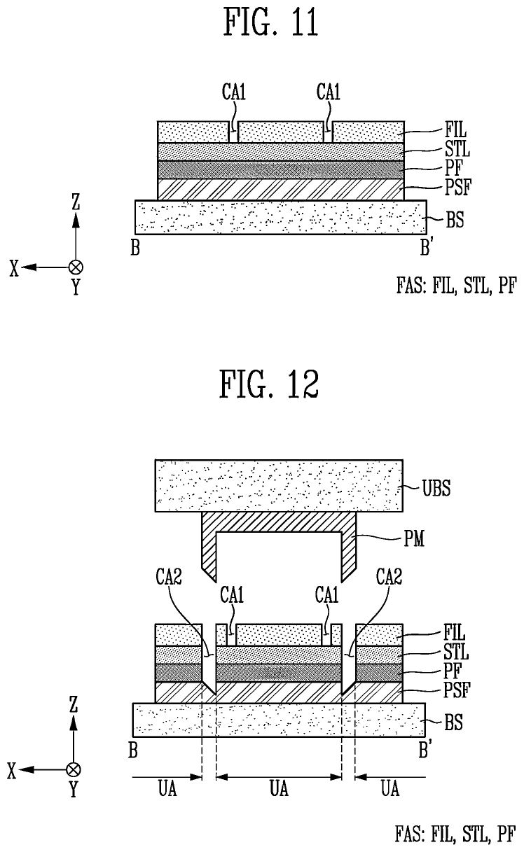

FIG. 9 to FIG. 12 illustrate schematic cross-sectional views of steps of a method of manufacturing a film assembly according to an embodiment. For better understanding and ease of description, FIG. 9 and FIG. 10 illustrate a schematic cross-sectional structure taken along the line A-A′ in FIGS. 6-8 of the film assembly FAS during a manufacturing process. FIG. 11 and FIG. 12 illustrate a schematic cross-sectional structure taken along the line B-B′ in FIGS. 6-8 of the film assembly FAS during a manufacturing process.

Referring to FIG. 4, the method of manufacturing the film assembly FAS may include disposing a film assembly on a base (S20), forming a first cutting area in the film assembly (S40), and forming a second cutting area in the film assembly (S60).

According to an embodiment, the method of manufacturing the film assembly FAS may be performed to provide the film assembly FAS having a first cutting area CA1 and a second cutting area CA2 and a plurality of unit areas UA.

For example, the film assembly FAS may be a stamp structure for transferring the light emitting elements LE by using a stamp method. To transfer the light emitting element LE by using the film assembly FAS, the film assembly FAS is divided into the plurality of unit areas UA. The light emitting element(s) LE disposed in each of the unit areas UA of the film assembly FAS may be coupled to a stamp head SHA (see, e.g., FIG. 17) in each of the divided process steps, and the stamp head SHA may transfer the separately provided light emitting element(s) LE to the pixel circuit layer PCL.

In some embodiments, the first cutting area CA1 may be cutting portions for providing an area in which a protective film FIL is removed after the film assembly FAS is provided to the stamp head SHA.

In some embodiments, the second cutting area CA2 may be cutting portions for distinguishing (or separating) the unit areas UA. For example, a process for manufacturing the second cutting area CA2 may be performed so that the unit areas UA may be separated.

The unit areas UA may be determined according to the shape of the second cutting area CA2. In some embodiments, the unit areas UA may be formed in a matrix structure according to X and Y directions. The shape of the unit areas UA is not limited thereto.

According to an embodiment, the film assembly FAS may be manufactured on a base BS for manufacturing a film. The film manufacturing base (which may be referred to as the film manufacturing base BS) may include a stage for manufacturing the film assembly FAS. The film manufacturing base may include a lower mold. The film manufacturing base may be referred to as a “base.”

The film assembly FAS may include a relatively rigid material, but the present disclosure is not limited thereto.

In some embodiments, a pin-hole PH may be formed in the film assembly FAS. The pin-hole PH may have a structure for aligning positions of layers for manufacturing the film assembly FAS. The pin-hole PH may penetrate (e.g., may extend through) at least the protective film FIL. For example, when a process for manufacturing a film assembly (e.g., when FAS is performed), a pin PN (see, e.g., FIG. 10) may be provided in the pin-hole PH, and the position of the film assembly FAS may be closely defined (e.g., may be fixed).

The pin-hole PH may be formed in (or on) each of first and second sides of the film assembly FAS. For example, the pin-hole PH may include a first pin-hole formed in the first side of the film assembly FAS and a second pin-hole formed in the second side of the film assembly FAS.

The shape of the pin-hole PH may be a circular shape or the like. In some embodiments, the pin-hole PH may penetrate (e.g., may extend through) the film assembly FAS and may include a groove formed in at least a portion of the film manufacturing base. For example, the pin-hole PH may penetrate a polymer lower film PSF, a base portion PF, a stamp layer STL, and the protective film FIL.

Hereinafter, steps of the manufacturing process of the film assembly FAS according to an embodiment will be described.

Referring to FIG. 4, FIG. 6, and FIG. 9, in the disposing of the film assembly on the base (S20), a plurality of layers forming the film assembly FAS may be disposed on the film manufacturing base BS for forming the cutting areas CA1 and CA2 of the film assembly FAS. In some embodiments, the polymer lower film PSF may be disposed on the film manufacturing base BS, and the plurality of layers for forming the film assembly FAS may be sequentially disposed on the polymer lower film PSF.

The polymer lower film PSF may be disposed between the base portion PF and the film manufacturing base BS, and when the second cutting area CA2 is formed in a subsequent process, a height deviation between the layers may be alleviated. For example, the polymer lower film PSF may be a buffer layer. The polymer lower film PSF may be a sacrificial layer. The polymer lower film PSF may include various resin materials (e.g., urethane or the like). However, the present disclosure is not limited thereto.

The plurality of layers forming the film assembly FAS may extend in one plane (e.g., a plane extending in the X direction and the Y direction). For example, the film assembly FAS may be formed on a substantially flat polymer lower film PSF.

In some embodiments, at least one end portion of the film assembly FAS may be wound around a roller. In other embodiments, the film assembly FAS may be provided in (or formed in) a flat shape as a whole without being wound on a roller. The film assembly FAS may include the base portion PF, the stamp layer STL, and the protective film FIL.

The base portion PF may be disposed on the stamp layer STL and the polymer lower film PSF. The base portion PF may support a lower portion of the stamp layer STL.

The base portion PF may include various hard or soft materials. For example, the base portion PF may include polyethylene terephthalate (PET), polycarboxylate ether (PCE), or the like. In other embodiments, the base portion PF may include a glass material. For example, the base portion PF may include ultra-thin glass (UTG). However, the present disclosure is not limited thereto.

The stamp layer STL may be disposed between the base portion PF and the protective film FIL. The stamp layer STL may form an area in which the light emitting element LE is disposed before being transferred to the pixel circuit layer PCL. For example, the stamp layer STL may be an adhesive layer.

The stamp layer STL may include a relatively flexible material. For example, the stamp layer STL may include polydimethylsiloxane (PDMS). However, the present disclosure is not limited thereto.

In some embodiments, the stamp layer STL may be configured to transmit an infrared laser. In such an embodiment, after the light emitting element LE is transferred onto the pixel circuit layer PCL by using the stamp layer STL, the laser bonding process may be performed so that the light emitting elements LE may be attached onto the pixel circuit layer PCL.

The protective film FIL may be disposed on the stamp layer STL. In some embodiments, the protective film FIL may be the outermost layer of the stamp layer STL. The protective film FIL may be a structure for protecting the stamp layer STL when processes are performed.

In some embodiments, the area in which the protective film FIL is formed may be formed wider than other layers (e.g., wider than the base portion PF and the stamp layer STL) of the film assembly FAS other than the protective film FIL. In some embodiments, the pin-hole PH may be formed in a partial area of the protective film FIL at where other layers of the film assembly FAS (e.g., the base portion PF and the stamp layer STL) other than the protective film FIL are not disposed. For example, the protective film FIL may have a first protective film portion disposed on the base portion PF and the stamp layer STL and a second protective film portion formed outside the base portion PF and the stamp layer STL. In some embodiments, the pin-hole PH may be formed in the second protective film portion and may not be formed in the first protective film portion.

At least a portion of the protective film FIL may be removed so that the light emitting element LE is disposed on the stamp layer STL in a later (or subsequent) process. The protective film FIL may include various resins (e.g., an olefin-based resin, urethane, and the like). However, the present disclosure is not limited thereto.

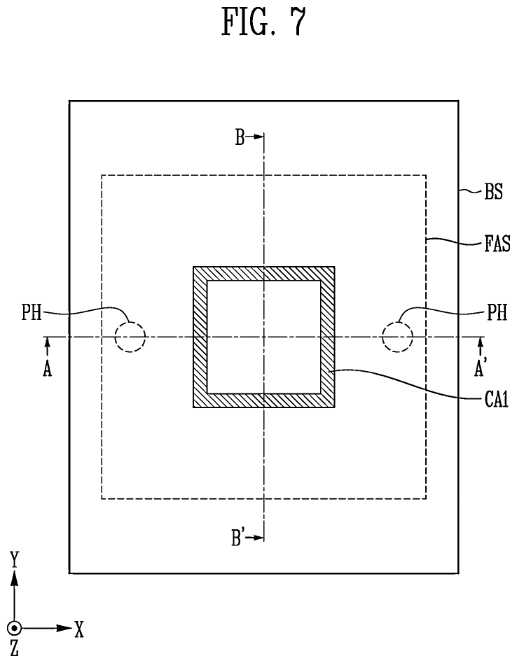

Referring to FIG. 4, FIG. 7, and FIG. 11, in the forming of the first cutting area in the film assembly (S40), at least a portion of the film assembly FAS may be cut.

Step S40 may include forming a half-cut structure in the film assembly FAS.

In some embodiments, the first cutting area CA1 may be manufactured to correspond to each of the unit areas UA to be manufactured. For example, the first cutting area CA1 may be manufactured in a closed-loop shape inside the unit areas UA to be manufactured.

In some embodiments, the area of the stamp layer STL in the first cutting area CA1 may be an area to which the light emitting element LE is attached in a later (or subsequent) process or step.

In step S40, at least a portion of the protective film FIL may be cut to manufacture the first cutting area CA1. For example, a cavity may be formed in at least a portion of the protective film FIL. In some embodiments, the first cutting area CA1 may be formed so that at least a portion of the stamp layer STL may be exposed.

The first cutting area CA1 may entirely penetrate (e.g., may extend entirely through) the protective film FIL, and the first cutting area CA1 may not penetrate the stamp layer STL and the base portion PF.

In some embodiments, the first cutting area CA1 may be manufactured by using a mold. However, the present disclosure is not limited thereto. In some embodiments, when the first cutting area CA1 is formed, a mold may be aligned by using the pin-hole PH.

In other embodiments, when the disposing of the film assembly on the film manufacturing base (S20) is performed, the film assembly FAS in which the first cutting area CA1 is previously formed may be provided on the film manufacturing base.

In such an embodiment, when manufacturing a separately prepared film assembly FAS, a protective film FIL having a hole (or opening) structure corresponding to the first cutting area CA1 may be disposed on the stamp layer STL. Accordingly, the film assembly FAS in which the first cutting area CA1 is provided may be provided on the film manufacturing base BS.

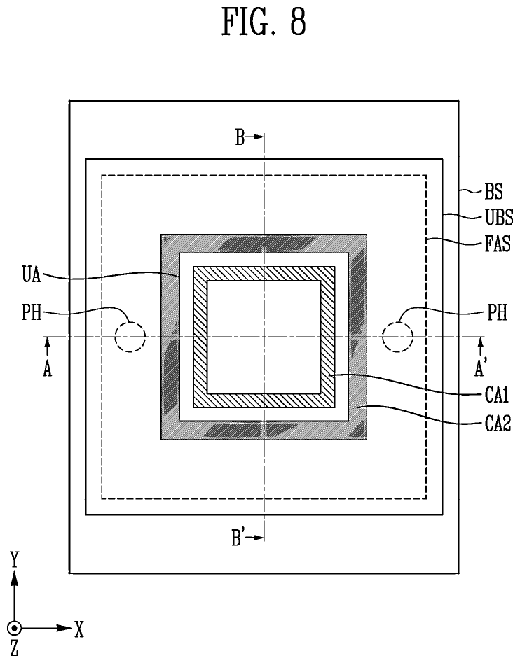

Referring to FIG. 4, FIG. 8, FIG. 10, and FIG. 12, in the forming of the second cutting area in the film assembly (S60), at least a portion of the film assembly FAS may be cut.

Step S60 may include forming a full-cut structure in the film assembly FAS.

In some embodiments, the second cutting area CA2 may be manufactured such that the unit areas UA to be manufactured are distinguished from each other. For example, the second cutting area CA2 may be manufactured in the form of a closed loop in an area between the unit areas UA to be manufactured.

The second cutting area CA2 may be formed relatively adjacent to the first cutting area CA1. The second cutting area CA2 may surround an outer edge of (e.g., may extend around an outer edge of) the first cutting area CA1 in a plan view. The second cutting area CA2 may entirely surround the outside of the first cutting area CA1 in a plan view.

Step S60 may include manufacturing the unit areas UA.

In step S60, the second cutting area CA2 may be manufactured by cutting so that a portion of the film assembly FAS is entirely penetrated. For example, the second cutting area CA2 may entirely penetrate the film assembly FAS, and at least a portion of the second cutting area CA2 may be inserted into at least a portion of the polymer lower film PSF.

In some embodiments, the second cutting area CA2 may be manufactured by using a pinnacle mold PM. For example, the pinnacle mold PM attached to an upper mold UBS may be provided, and the pin PN connected to the upper mold UBS may be provided. The upper mold UBS may be moved downwardly so that the pin PN is inserted into the pin-hole PH and the second cutting area CA2 may be provided by the pinnacle mold PM cutting at least a portion of the film assembly FAS.

The pinnacle mold PM may have a shape corresponding to the shape of the second cutting area CA2 to be manufactured and may include a relatively hard material.

By performing step S60, the film assembly FAS including the unit areas UA spaced apart from each other may be manufactured.

In some embodiments, as described above, after the first cutting area CA1 is formed, the second cutting area CA2 may be formed.

Experimentally, when the first cutting area CA1 and the second cutting area CA2 are simultaneously manufactured, there may be a risk of manufacturing defects in the film assembly FAS. For example, when the first cutting area CA1 and the second cutting area CA2 are formed in the film assembly FAS by using the pinnacle mold including a structure for forming each of the first cutting area CA1 and the second cutting area CA2, because there may be manufacturing errors in the protruding structure formed in the pinnacle mold, there is a risk that the first cutting area CA1 and the second cutting area CA2 may not be properly formed. In this case, the structure of the film assembly FAS may not be carefully prepared and defects may occur during the transfer process of the light emitting element LE.

However, according to an embodiment of the present disclosure, the first cutting area CA1 and the second cutting area CA2 may be provided in (e.g., may be formed in) separate process steps, and accordingly, the structure of the film assembly FAS may be robustly provided and process defects during the manufacturing process of the display device 10 may be reduced or prevented.

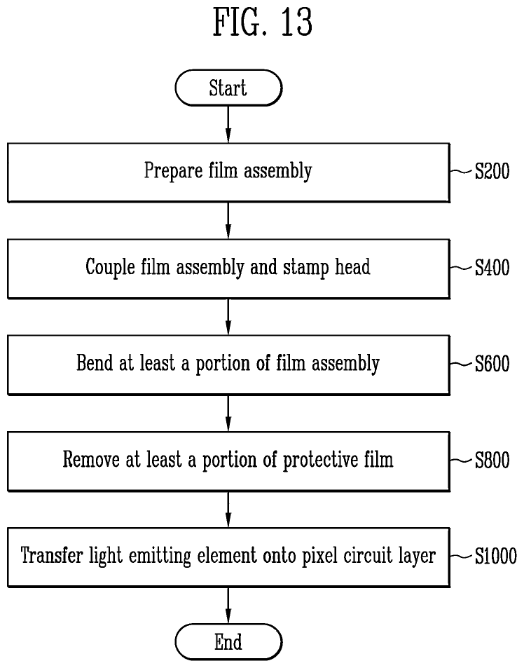

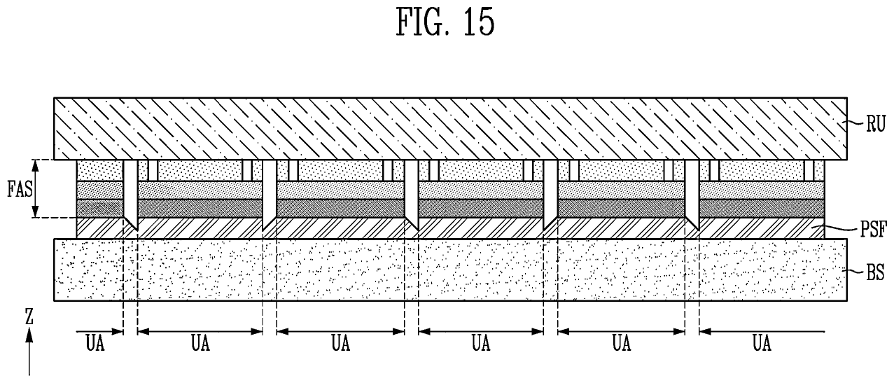

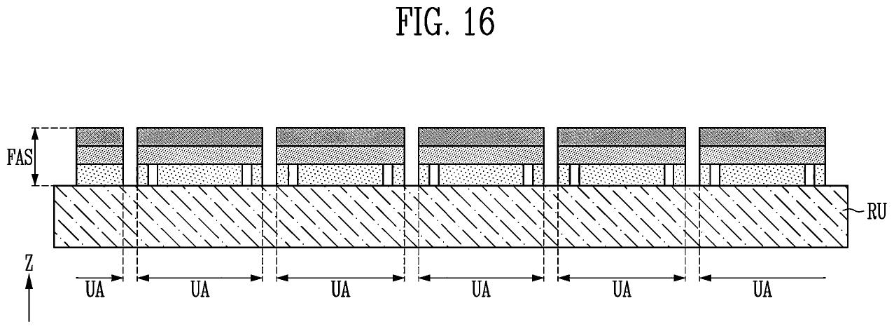

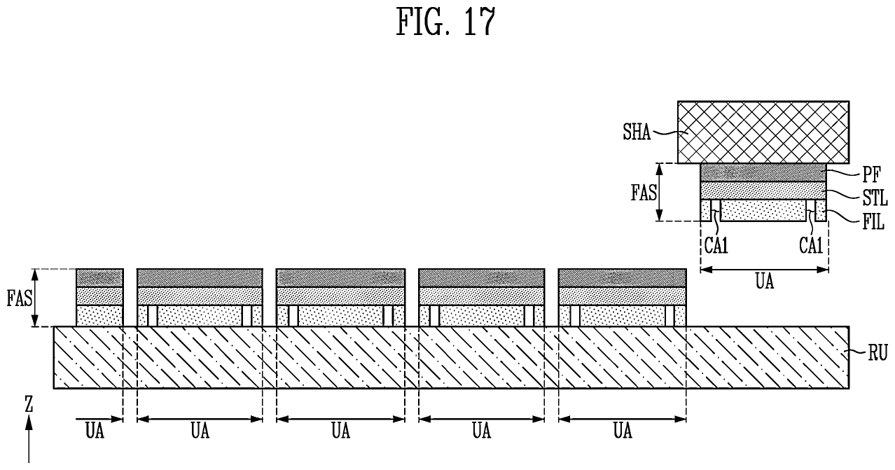

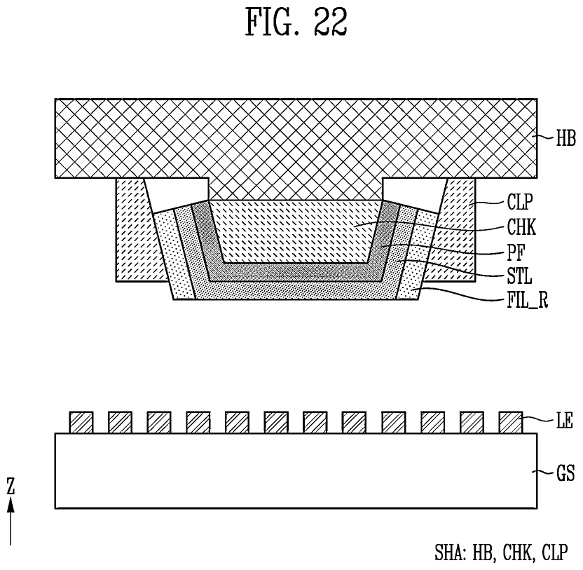

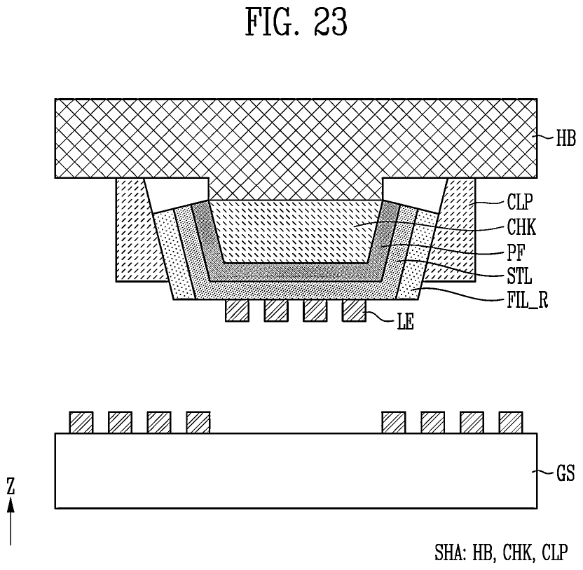

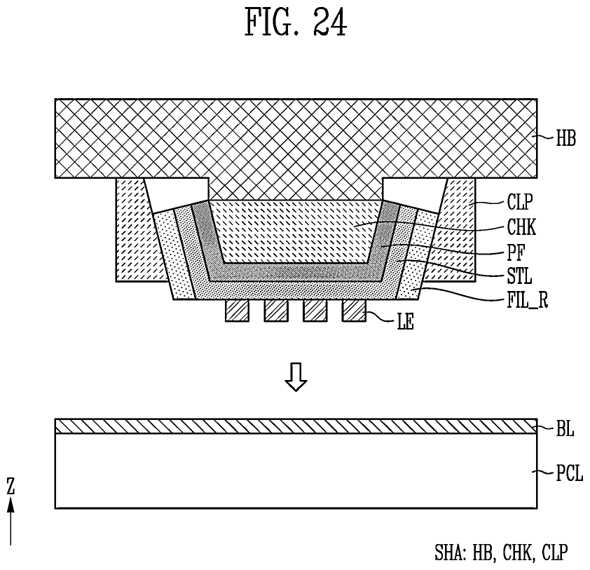

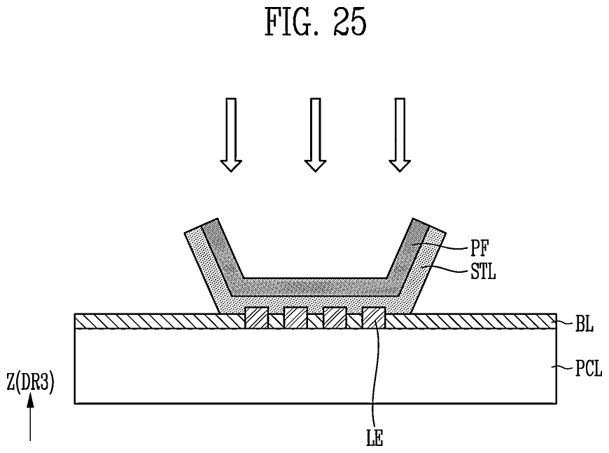

Hereinafter, a method of manufacturing the display device 10 by using the film assembly FAS according to an embodiment will be described with reference to FIG. 13 to FIG. 25. Descriptions that may be redundant to those provided above may be simplified or may not be repeated.

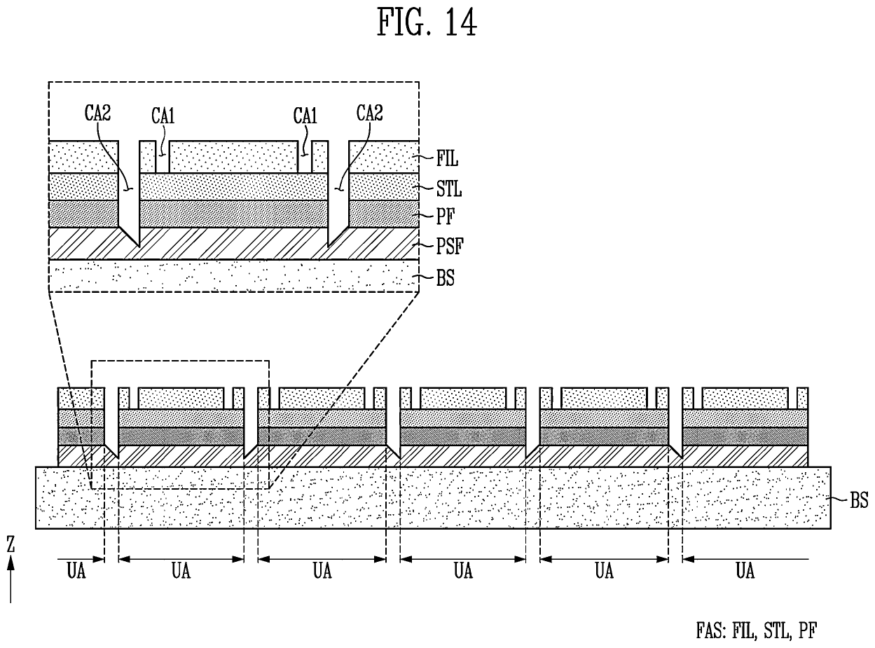

FIG. 13 is a flowchart describing steps of a method of manufacturing a display device according to an embodiment. FIG. 14 to FIG. 25 illustrate cross-sectional views of steps of a method of manufacturing a display device according to an embodiment.

Referring to FIG. 13, the method of manufacturing the display device 10 according to an embodiment may include preparing a film assembly (S200), coupling the film assembly and a stamp head (S400), bending at least a portion of the film assembly (S600), removing at least a portion of a protective film (S800), and transferring a light emitting element onto a pixel circuit layer (S1000).

Referring to FIG. 13 and FIG. 14, in the preparing of the film assembly (S200), the film assembly FAS including the first and second cutting areas CA1 and CA2 may be provided.

In step S200, the film assembly FAS having the unit areas UA may be provided on the film manufacturing base BS, and the protective film FIL of the film assembly FAS may be disposed on the upper side with respect to the Z direction.

Referring to FIG. 13 and FIG. 15 to FIG. 18, in the coupling of the film assembly and the stamp head (S400), the film assembly FAS and the stamp head SHA may be attached so that the base portion PF of the film assembly FAS faces the stamp head SHA.

In step S400, the position of the film assembly FAS provided on the film manufacturing base BS may be changed by using a reversing unit RU. For example, after the position of the film assembly FAS is changed so that the protective film FIL is disposed on the reversing unit RU, as the reversing unit RU is overturned, the disposition state of the film assembly FAS may be changed so that the protective film FIL of the film assembly FAS faces upwardly.

In some embodiments, in step S400, the polymer lower film PSF may still be disposed on the film manufacturing base BS, and as the film assembly FAS is disposed on the reversing unit RU, the film assembly FAS and the polymer lower film PSF may be spaced apart from each other.

The reversing unit RU may be reversed in various ways. For example, a rotation axis is formed on one side of the reversing unit RU so that the reversing unit RU may be rotated based on the rotation axis. However, the present disclosure is not limited thereto.

In step S400, the unit area UA of the film assembly FAS may be coupled to the stamp head SHA. In some embodiments, a portion of the film assembly FAS in one or more unit areas UA may be coupled to the stamp head SHA. In this case, because the disposition state of the film assembly FAS is changed by the reversing unit RU, the base portion PF may face outwardly so the base portion PF may be adjacent to the stamp head SHA.

In some embodiments, the stamp head SHA may include a head base HB, a fixing portion CHK, and a clamp portion CLP.

The fixing portion CHK may be configured to couple the base portion PF and the stamp layer STL to the stamp head SHA in various ways. For example, the fixing portion CHK may include an electrostatic chuck, an adhesive chuck, a vacuum chuck, or a porous vacuum chuck.

The clamp portion CLP may clamp an object. For example, the clamp portion CLP may firmly fix the position of the film assembly FAS. For example, the clamp portion CLP may be disposed on both sides of the fixing portion CHK and may push (or may squeeze) the film assembly FAS adjacent to the fixing portion CHK from both sides.

In some embodiments, the method in which the clamp portion CLP and the fixing portion CHK fix the film assembly FAS is not limited to the examples shown in the drawings. For example, the method in which the film assembly FAS is fixed may be variously changed. For example, the clamp may be formed on a stage provided separately from the stamp head SHA.

In step S400, the base portion PF, the stamp layer STL, and the protective film FIL may be disposed on the fixing portion CHK, and the position thereof may be fixed. Accordingly, the protective film FIL may face downwardly, and the base portion PF may face upwardly (e.g., toward the stamp head SHA).

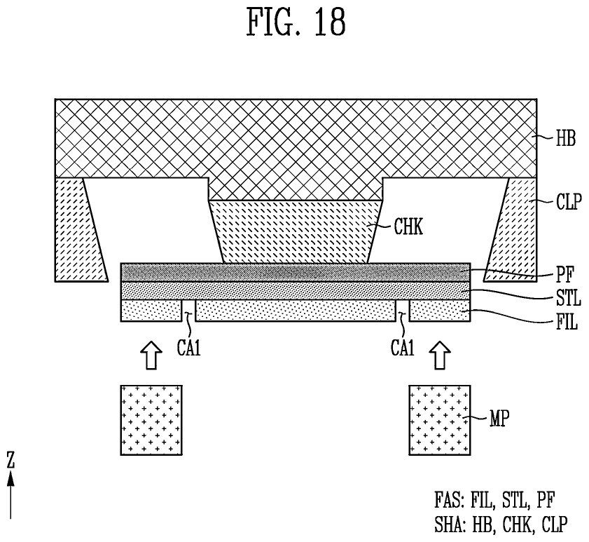

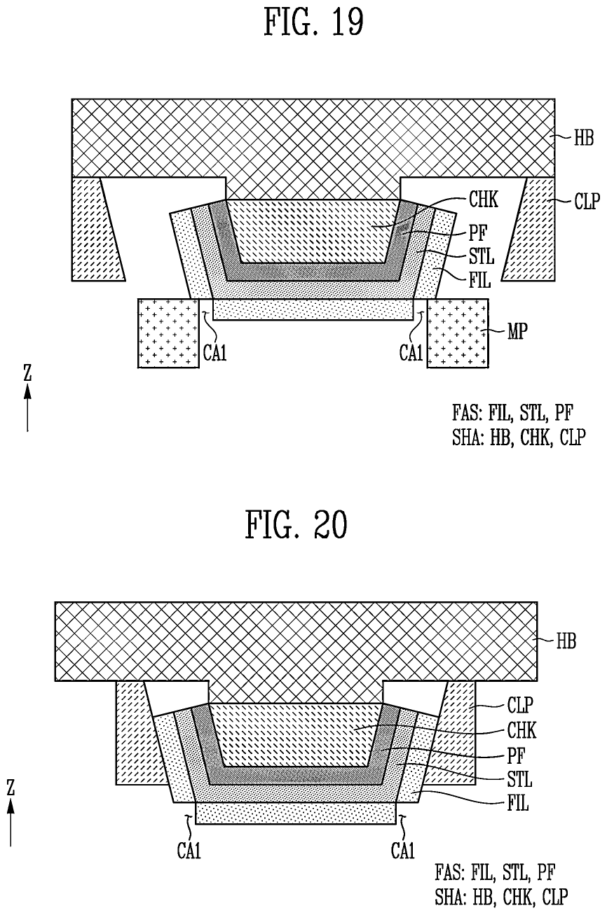

Referring to FIG. 13, FIG. 18, and FIG. 19, in the bending of at least a portion of the film assembly (S600), the film assembly FAS may be bent.

In some embodiments, a moving portion MP may be provided. The moving portion MP may move in a vertical direction (e.g., in a direction parallel to the Z-direction) and may be configured to push at least a portion of the film assembly FAS in the Z-direction.

In step S600, the moving portion MP may push the edge of the film assembly FAS, and the edge portions of the film assembly FAS may be bent. Edge portions of the bent film assembly FAS may be adjacent to the fixing portion CHK.

In step S600, an area in which the film assembly FAS is bent by the moving portion MP may be determined by the first cutting area CA1. For example, the first cutting area CA1 may be formed in at least a portion of the film assembly FAS so that a half-cut structure may be formed, and the edge portion of the film assembly FAS may be appropriately bent based on the first cutting area CA1.

In some embodiments, the method of bending the film assembly FAS is not limited to the above-described examples. For example, a separate chuck module may be provided so that the film assembly FAS may be bent.

As step S600 is performed, the protective film FIL may have an area facing downwardly and an area facing toward a side by being folded by the moving portion MP.

The method of bending the protective film FIL is not limited to the above-described examples, and various suitable process methods may be applied to bend the protective film FIL.

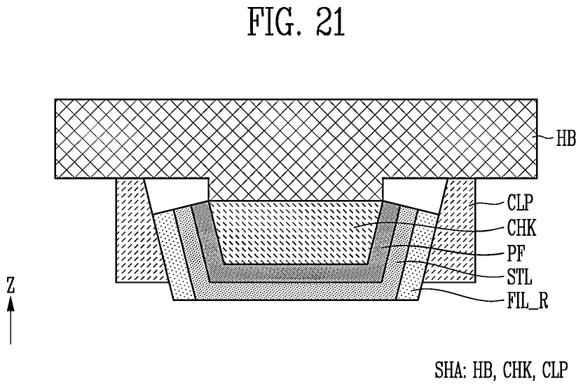

Referring to FIG. 13, FIG. 20, and FIG. 21, in the removing of at least a portion of the protective film (S800), at least a portion of the protective film FIL facing downwardly, that is, an area of the protective film FIL that is not bent in the previous process step, may be removed.

In step S800, a portion of the protective film FIL surrounded by the first cutting area CA1 may be removed. Various suitable methods, such as a method of physically removing a portion of the protective film FIL, may be used, but the present disclosure is not limited thereto.

As step S800 is performed, a portion of the protective film FIL may be removed, and a portion of the protective film FIL may still be disposed in an area adjacent to the clamp portion CLP, which may be referred to as the remaining protective film FIL_R.

In step S800, a portion (e.g., a lower surface) of the stamp layer STL may be exposed. Accordingly, an area in which the light emitting element LE may be disposed may be formed in the stamp layer STL.

According to an embodiment, one surface of the stamp layer STL on which the light emitting elements LE are disposed may be covered by the protective film FIL until step S800 is performed. For example, when the light emitting elements LE are disposed on the stamp layer STL, at least a portion of the protective film FIL may be removed so that the risk of contamination of the light emitting elements LE may be significantly reduced.

Referring to FIG. 13 and FIG. 22 to FIG. 25, in the transferring of the light emitting element onto the pixel circuit layer (S1000), the light emitting elements LE provided on the stamp layer STL may be disposed on the pixel circuit layer PCL.

Before step S1000 is performed, the light emitting elements LE may be formed on a growth substrate GS (e.g., a wafer). For example, after the semiconductor layers are epitaxially grown on the growth substrate GS, the semiconductor layers may be etched, and accordingly, separately prepared light emitting elements LE may be manufactured.

In step S1000, the stamp head SHA may be adjacent to the light emitting elements LE on the growth substrate GS, and the light emitting elements LE may be separated from the growth substrate GS by various suitable processes (e.g., laser lift-off and the like). Accordingly, the light emitting elements LE are supported by the fixing portion CHK and the clamp portion CLP and may be coupled to one surface of the stamp layer STL exposed by the remaining protective film FIL_R. In some embodiments, the number of light emitting elements LE attached to the stamp layer STL may be determined based on the area of the unit area UA.

In step S1000, the light emitting elements LE attached to the stamp layer STL may be moved onto the pixel circuit layer PCL. In some embodiments, the pixel electrode AE and the common electrode CE may be patterned on the pixel circuit layer PCL, and the bonding layer BL may be disposed. When an infrared laser or the like is applied, the bonding layer BL may fix the light emitting elements LE onto the pixel circuit layer PCL. In some embodiments, the bonding layer BL may be an adhesive layer. The bonding layer BL may include an anisotropic conductive paste (ACP).

In step S1000, after the light emitting elements LE are disposed on the bonding layer BL, the fixing portion CHK and the clamp portion CLP may release the fixing operation for the stamp layer STL and the base portion PF. Accordingly, the light emitting elements LE, the stamp layer STL, and the base portion PF may be disposed on the pixel circuit layer PCL. In addition, a laser bonding process may be performed so that the positions of the light emitting elements LE may be fixed, and the light emitting elements LE may be transferred onto the pixel circuit layer PCL.

Thereafter, the stamp layer STL and the base portion PF on the pixel circuit layer PCL after the light emitting elements LE are disposed may be removed therefrom, and the bonding layer BL may also be removed, thereby providing the display device 10 according to an embodiment.

While the present disclosure has been shown and described with reference to embodiments thereof, it will be understood by those skilled in the art that various changes in forms and details may be made therein without departing from the spirit and scope of the present disclosure as defined by the appended claims and their equivalents.

Therefore, the technical scope of the present disclosure may be determined by on the technical scope of the accompanying claims and their equivalents.

What is claimed is:

1. A method of manufacturing a film assembly for transferring a light emitting element, the film assembly comprising: a base portion; a stamp layer on the base portion; and a protective film on the stamp layer, the method comprising:
forming a first cutting area in the film assembly comprising exposing at least a portion of the stamp layer; and
forming a second cutting area in the film assembly comprising entirely penetrating the film assembly,
wherein the forming of the second cutting area is performed after the forming of the first cutting area.

2. The method of manufacturing the film assembly of claim 1, wherein the forming of the first cutting area comprises entirely penetrating the protective film but not entirely penetrating the base portion and the stamp layer.

3. The method of manufacturing the film assembly of claim 1, wherein the forming of the second cutting area comprises forming a plurality of unit areas that are separated from each other.

4. The method of manufacturing the film assembly of claim 3, wherein the plurality of unit areas is determined based on a shape of the second cutting area.

5. The method of manufacturing the film assembly of claim 1, wherein the forming of the second cutting area comprises cutting at least a portion of the film assembly by using a pinnacle mold.

6. The method of manufacturing the film assembly of claim 5, wherein the film assembly has a pin-hole for aligning a position of the pinnacle mold, and
wherein the pin-hole penetrates at least the protective film.

7. The method of manufacturing the film assembly of claim 6, wherein at least a portion of the protective film is not on the base portion and the stamp layer, and
wherein the pin-hole is in the at least a portion of the protective film.

8. The method of manufacturing the film assembly of claim 6, wherein the pin-hole comprises a first pin-hole formed in a first side of the film assembly and a second pin-hole formed in a second side of the film assembly.

9. The method of manufacturing the film assembly of claim 1, wherein, in the forming of the second cutting area, the film assembly is on a film manufacturing base, and a polymer lower film is between the film manufacturing base and the base portion.

10. A film assembly for transferring a light emitting element, the film assembly comprising:
a base portion;
a stamp layer on the base portion; and
a protective film on the stamp layer,
wherein a first cutting area is formed in the protective film but is not formed in the stamp layer and the base portion, and
wherein a second cutting area entirely penetrates the base portion, the stamp layer, and the protective film.

11. A method of manufacturing a display device, the method comprising:
preparing a film assembly, the film assembly comprising a base portion, a stamp layer on the base portion, and a protective film on the stamp layer;
coupling the film assembly and a stamp head;
bending at least a portion of the film assembly;
removing at least a portion of the protective film; and
transferring a light emitting element onto a pixel circuit layer by using the film assembly coupled to the stamp head,
wherein the film assembly has a first cutting area and a second cutting area,
wherein the first cutting area is formed in the protective film but is not formed in the stamp layer and the base portion, and
wherein the second cutting area entirely penetrates the base portion, the stamp layer, and the protective film.

12. The method of manufacturing the display device of claim 11, wherein the film assembly comprises a plurality of unit areas defined by the second cutting area, and
wherein the coupling of the film assembly and the stamp head comprises coupling a portion of the film assembly in at least one of the plurality of unit areas to the stamp head.

13. The method of manufacturing the display device of claim 11, wherein the bending of at least a portion of the film assembly comprises bending an edge portion of the film assembly based on the first cutting area.

14. The method of manufacturing the display device of claim 13, wherein the removing at least a portion of the protective film comprises:
removing at least a portion of the protective film surrounded by the first cutting area; and
exposing at least a portion of the stamp layer.

15. The method of manufacturing the display device of claim 11, wherein the light emitting element comprises a flip chip type micro light emitting diode.
